(19) United States
(12) Patent Application Publication
(10) Pub. No.: US 2010/0311241 A1
(43) Pub. Date: Dec. 9, 2010

(54) THREE-STATE MASK AND METHOD OF MANUFACTURING SEMICONDUCTOR DEVICE USING THE SAME

(76) Inventor: Jae-Hyun Kang, Suwon-si (KR)

Correspondence Address: SHERR & VAUGHN, PLLC, 620 HERNDON PARKWAY, SUITE 320, HERNDON, VA, 20170, US

(21) Appl. No.: 12/565,994

(22) Filed: Sep. 24, 2009

(30) Foreign Application Priority Data
Oct. 6, 2008 (KR) 10-2008-0097634

(51) Int. Cl. H01L 21/768; G03F 1/00

(52) U.S. Cl. 438/675; 430/5; 257/E21.585

(57) ABSTRACT

A three-state mask, which is used during exposure of a lithography process and formed in a regular pattern, includes a first transmission region to transmit substantially all incident light, second transmission regions to transmit a portion of incident light, and shield regions to block transmission of light. Therefore, the three-state mask shortens two lithography processes into one lithography process, eliminates misalignment between a via hole and a trench, prevents lowering of a sheet resistance (Rₛ) due to misalignment, simplifies a dual damascene process, reduces the number of masks used in the dual damascene process, and thus contributes to reduction of manufacturing costs of the semiconductor device.

The present application claims priority under 35 U.S.C. 119 to Korean Patent Application No. 10-2008-0097634 (filed on Oct. 6, 2008), which is hereby incorporated by reference in its entirety.

### BACKGROUND

Hereinafter, related masks used during a lithography process and a related method of manufacturing a semiconductor device using the same will be described with reference to the accompanying drawings. FIGS. 1A to 1J are longitudinal-sectional views illustrating a method of manufacturing a semiconductor device using related masks. FIG. 2 is a plan view of a mask 14 shown in FIG. 1A, and FIG. 3 is a plan view of a mask 60 shown in FIG. 1F.

With reference to FIG. 1A, the upper surface of an insulating layer 10, stacked on a semiconductor substrate, is coated with a photoresist 12. Thereafter, the photoresist 12 is exposed and developed using a two-state mask 14, thereby forming a first photoresist pattern 12A to expose a hole region 16, as shown in FIG. 1B. With reference to FIG. 1A, which is a longitudinal-sectional view of FIG. 2, taken along the line A-A′, the two-state mask 14 for via formation includes a region 24, which entirely transmits light, and regions 20 and 22, which do not transmit light. That is, the mask 14 includes two regions having different light transmittances, and thus is called ‘a two-state mask’. Thereafter, as shown in FIG. 1C, the insulating layer 10 is etched using the first photoresist pattern 12A as an etching mask, thereby forming a hole 30. Thereafter, the first photoresist pattern 12A is removed. As shown in FIG. 1D, the upper surface of the etched insulating layer 10A is coated again with a photoresist 40 so as to fill the hole 30. Thereafter, as shown in FIG. 1E, most of the photoresist 40 is removed such that only the photoresist 40 filling a designated portion of the hole 30 remains. As shown in FIG. 1F, the upper surface of the insulating layer 10A including the remaining photoresist 40A is coated again with a photoresist 50. Thereafter, a second photoresist pattern 50A, as shown in FIG. 1G, is formed by a lithography process using the two-state mask 60 for trench formation. With reference to FIG. 1F, which is a longitudinal-sectional view of FIG. 3, taken along the line B-B′, the two-state mask 60 for trench formation includes a region 64, which entirely transmits light, and regions 62 and 66, which do not transmit light. As shown in FIG. 1H, the insulating film 10A is secondarily etched using the second photoresist pattern 50A as an etching mask, thereby forming a trench T and completing the hole H. Thereafter, the second photoresist pattern 50A and the remaining photoresist 40A are removed. As shown in FIG. 1I, a metal material 70 is provided on the upper surface of the insulating layer 10B so as to fill the trench T and the hole H, and then the metal material 70 is planarized until the upper surface of the insulating layer 10B is exposed, thereby forming a metal layer 70A filling the hole H and the trench T, as shown in FIG. 1J.

The above-described related masks 14 and 60 respectively include the regions 24 and 64, which entirely transmit light, and the regions 20, 22 and 62, 66, which do not transmit light or transmit only a minimal portion of the light, for example, only 6% of the total amount of light. If the metal line 70A is formed in the insulating layer 10B by a dual damascene process using these two-state masks 14 and 60, some problems, which will be described below, are raised.

First, since the two masks 14 and 60 are used, a manufacturing process of the semiconductor device is complicated and a plurality of masks is required, thereby a manufacturing cost of the semiconductor device is raised.

Second, since the trench T is formed after the formation of the hole H, the opened region of the second photoresist pattern 50A to form the trench T may be misaligned with the hole H. If the hole H and the trench T are misaligned with each other, a sheet resistance (Rn) of the metal line 70A is increased.

### SUMMARY

Embodiments relate to a mask and a method of manufacturing a semiconductor device using the same, and more particularly, to a three-state mask and a method of manufacturing a semiconductor device using the same. Embodiments relate to a three-state mask and a method of manufacturing a semiconductor device using the same. Embodiments relate to a three-state mask, which may reduce two exposure processes during lithography into one exposure process.

Embodiments relate to a method of manufacturing a semiconductor device using a three-state mask, in which a dual damascene process is shortened and a misalignment problem is eliminated using the three-state mask. Embodiments relate to a three-state mask used during exposure of a lithography process and formed in a regular pattern, which includes a first transmission region to transmit substantially all incident light, second transmission regions to transmit a portion of incident light, and shield regions to block transmission of light.

Embodiments relate to a method of manufacturing a semiconductor device which includes preparing a three-state mask including a first transmission region to transmit substantially all incident light, second transmission regions to transmit a portion of incident light, and shield regions to substantially block transmission of light, forming an insulating layer over the upper surface of a semiconductor substrate, coating a photoresist to the upper surface of the insulating layer, patterning the photoresist by a lithography process using the three-state mask, and simultaneously forming a via hole and a trench by transcribing the obtained photoresist pattern into the insulating layer.

### DRAWINGS

FIGS. 1A to 1J are longitudinal-sectional views illustrating a method of manufacturing a semiconductor device using related masks.

FIG. 2 is a plan view of a mask shown in FIG. 1A.

FIG. 3 is a plan view of a mask shown in FIG. 1F.

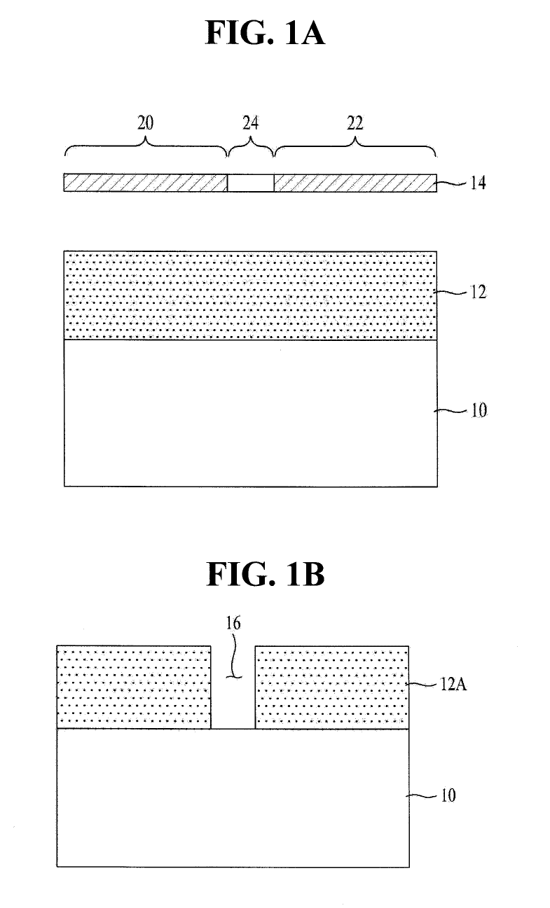

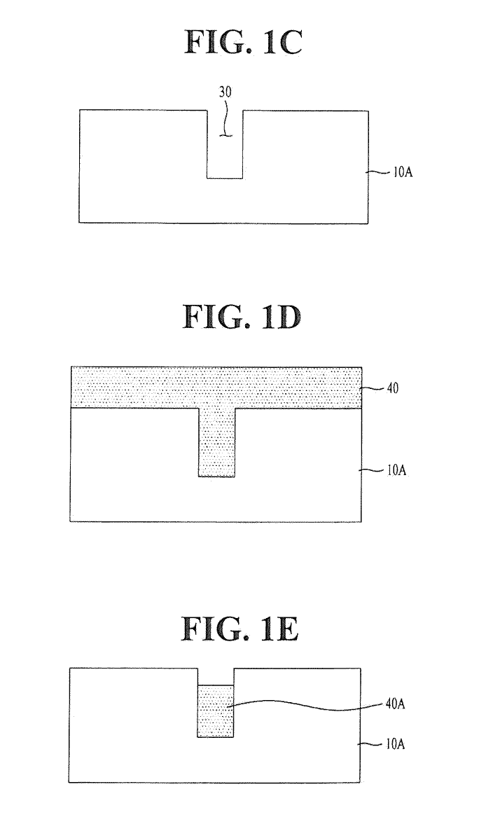

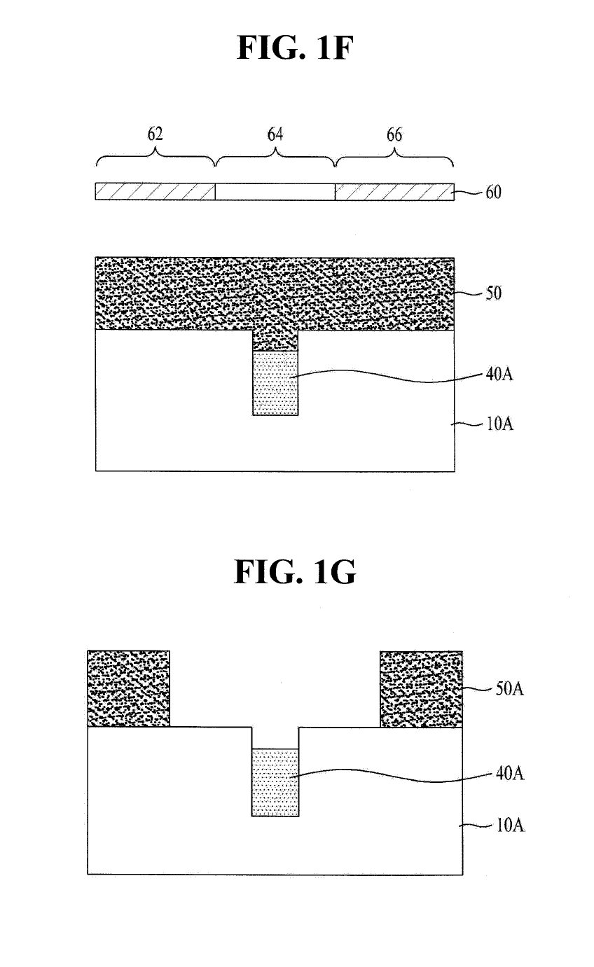

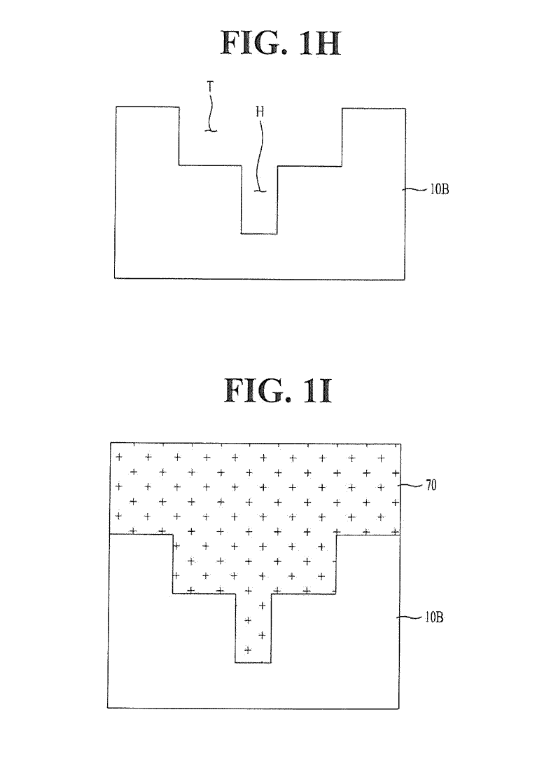

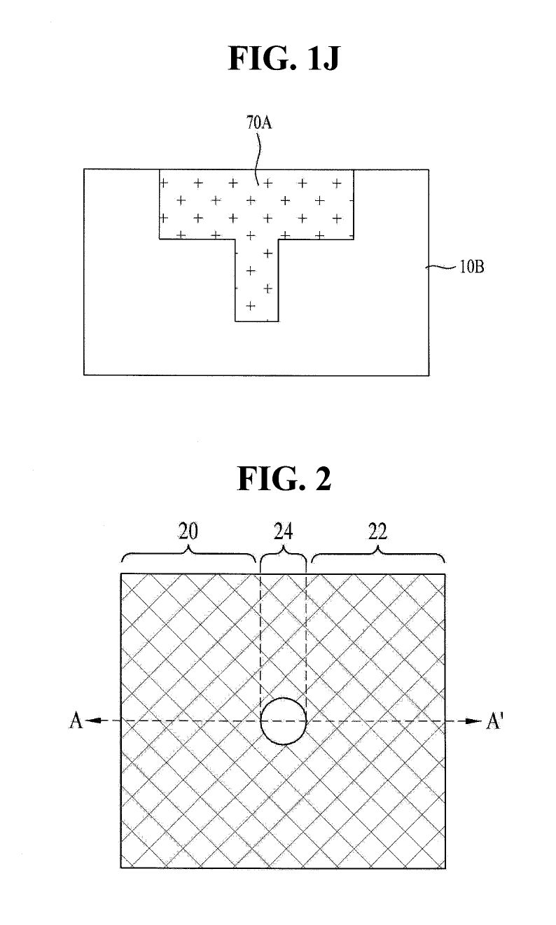

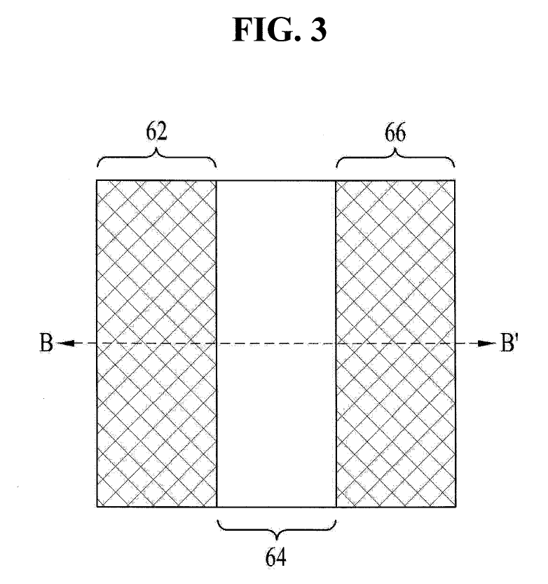

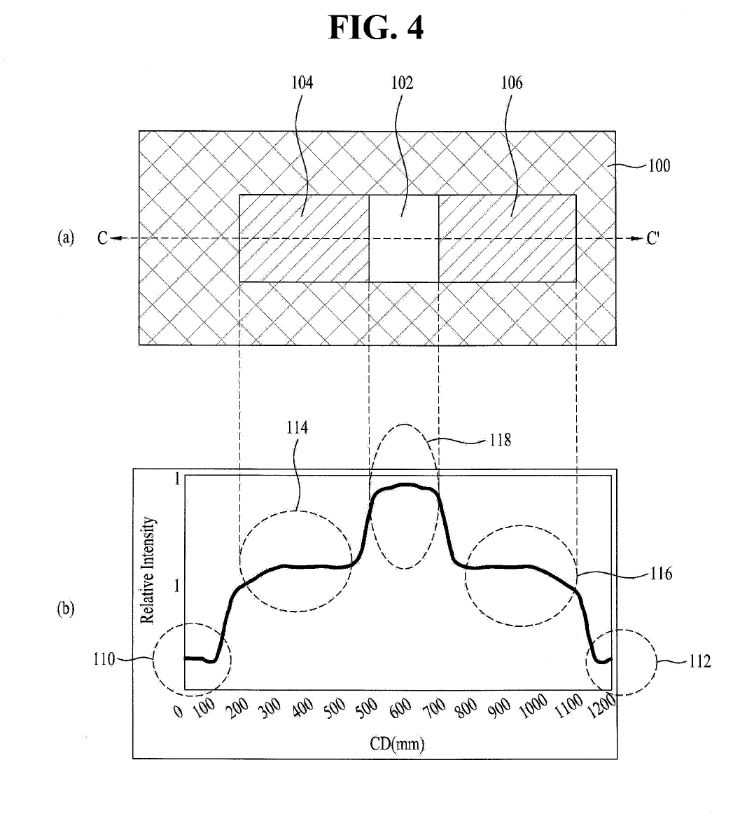

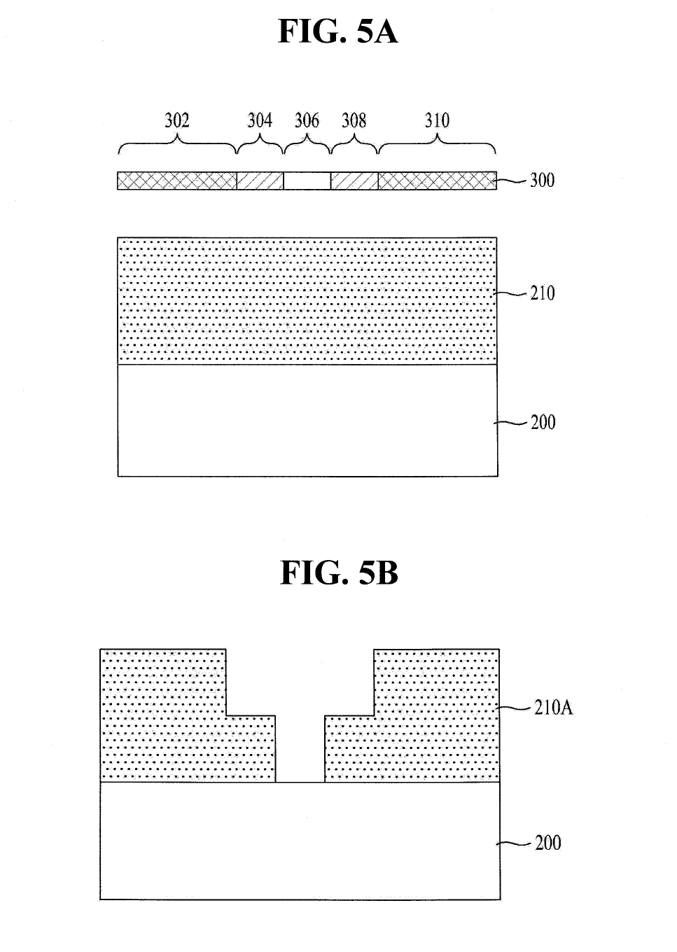

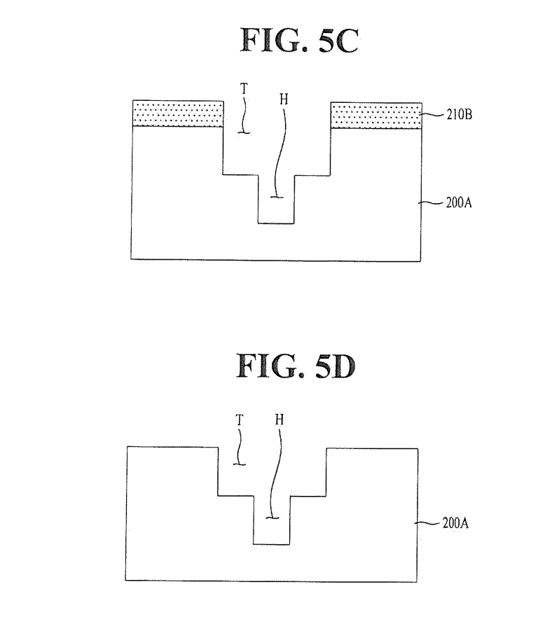

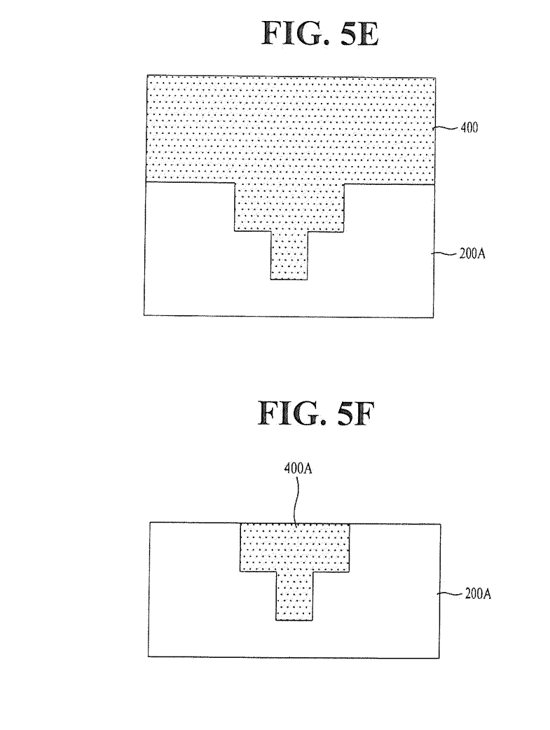

Example FIG. 4 includes a plan view of a three-state mask in accordance with embodiments, and a graph illustrating intensity of light passed through the three-state mask.

Example FIGS. 5A to 5F are longitudinal-sectional views illustrating a method of manufacturing a semiconductor device in accordance with embodiments.

### DESCRIPTION

Hereinafter, a three-state mask in accordance with embodiments will be described with reference to the accompanying drawings. Example FIG. 4 includes a plan view (a) of the three-state mask in accordance with embodiments, and a graph (b) illustrating intensity of light passed through the three-state mask. In the graph (b) shown in example FIG. 4, a horizontal axis represents a critical dimension (CD), and a vertical axis represents a relative intensity of light.

The three-state mask shown in example FIG. 4 may be used for exposure during a lithography process, and has a regular pattern. The three-state mask may include a first transmission part or region 102, second transmission parts or regions 104 and 106, and a shield part or region 100.

The first transmission part 102 may serve to transmit substantially all incident light, and thus is made of a substantially transparent material. The second transmission parts 104 and 106 may serve to transmit a portion of incident light. In accordance with embodiments, the second transmission parts 104 and 106 may transmit 20% to 30% of incident light. For example, the second transmission parts 104 and 106 may be made of Molybdenum Silicide (MoSi). The second transmission parts 104 and 106 may perform Phase Shift Masking (PSM) of the portion of light incident on these regions. The shield part 100 serves to prevent transmission of light. For this reason, the shield part 100 may be made of chrome (Cr). The shield part 100 corresponds to a background of a region which transmits light.

The above mask includes three parts, with differing light transmissivities, as described above, and thus is called ‘a three-state mask’. In accordance with embodiments, the shield part 100 may be formed in a shape or region surrounding the first transmission part 102, and the second transmission parts 104 and 106, as shown in example FIG. 4. Further, the second transmission parts 104 and 106 may be opposite to each other such that the first transmission part 102 is interposed between the second transmission parts 104 and 106. Although example FIG. 4 illustrates the first transmission part 102 having a rectangular shape, the first transmission part 102 may have a ring shape. The three-state mask in accordance with embodiments is not limited to the shape shown in example FIG. 4, and may have various shapes according to desired patterns.

With reference to the graph (b) shown in example FIG. 4, the first transmission part 102 may transmit substantially all incident light, and thus an intensity 118 of light having passed through the first transmission part 102 is maximal. The second transmission parts 104 and 106 may transmit a part of the incident light, and thus intensities 114 and 116 of light having passed through the second transmission parts 104 and 106 are intermediate. The shield part 100 does not substantially transmit light, but rather shields light, and thus intensities 110 and 112 of light having passed through the shield part 100 are close to zero.

Since the intensities of light having passed through the first transmission part 102 and the second transmission parts 104 and 106 are different, as described above, the three-state mask in accordance with embodiments may be applied to various fields using a lithography process. Hereinafter, a method of manufacturing a semiconductor device using the three-state mask in accordance with embodiments, and particularly, example embodiments of a dual damascene process, will be described with reference to the accompanying drawings.

Example FIG. 5A to 5F are longitudinal-sectional views illustrating a method of manufacturing a semiconductor device in accordance with embodiments. With reference to example FIG. 5A, a three-state mask 300 in accordance with embodiments may be prepared. The three-state mask 300 may include a first transmission part or region 306, second transmission parts or regions 304 and 308, and shield parts or regions 302 and 310, as described above. For example, the first transmission part 306, the second transmission parts 304 and 308, and the shield parts 302 and 310 may respectively correspond to the first transmission part 102, the second transmission parts 104 and 106, and the shield part 100 of example FIG. 4A. That is, the first transmission part 306 may transmit substantially all light incident upon the mask 300, the second transmission parts 304 and 308 may transmit a part of light incident upon the mask 300, and the shield parts 302 and 310 may prevent transmission of light incident upon the mask 300.

Thereafter, as shown in example FIG. 5A, an insulating layer 200 may be formed over the upper surface of a semiconductor substrate. Here, the insulating layer 200 may be made of an insulating material having a low k, such as Fluoro-Silicate Glass (FSG), Black Diamond (BD), or a porous oxide. BD is characterized by a lower k than that of FSG. A photoresist 210 may be coated to the upper surface of the insulating layer 200.

Thereafter, the photoresist 210 may be patterned, as shown in example FIG. 5B, by carrying out a lithography process using the three-state mask 300 shown in example FIG. 5A. With reference to example FIG. 4B, the intensity 118 of light having passed through the first transmission part 306 and the intensities 114 and 116 of light having passed through the second transmission parts 304 and 308 are different, and thus the photoresist 210 is patterned in a corresponding shape as shown in example FIG. 5B. That is, the first transmission part 306 transmits light to a region of the photoresist 210, at which a via hole H will be formed later, and the second transmission parts 304 and 308 transmit light to a region of the photoresist 210, at which a trench H will be formed later. As described above, the intensity 118 of light having reaching the region, at which the via hole H will be formed, is maximal, and the intensities 114 and 116 having reached the region, at which the trench T will be formed, is intermediate.

More concretely, the photoresist 210 is exposed using the above-described three-state mask 300. Thereafter, the photoresist 210 at the region exposed by light having passed through the first transmission part 306, may be entirely dissolved by a developing solution. The photoresist 210 at the regions exposed by light having passed through the second transmission parts 304 and 308 may be partially dissolved by the developing solution. A part of the total height of the photoresist 210, for example, half of the total height of the photoresist 210 may be dissolved. The photoresist 210 at the regions shielded from light by the shield parts 302 and 310 may be scarcely dissolved by the developing solution. Therefore, a photoresist pattern 210A shown in example FIG. 5B may be formed. Although this embodiment illustrates that the photoresist 210 is positive, the same principle may be applied to a negative photoresist. In accordance with embodiments, the second transmission parts 304 and 308 adjust light transmissivity, and are capable of controlling a height of the photoresist 210 to be dissolved.

As shown in example FIG. 5C, the insulating layer 200 may be etched by a dry-etching method, for example, Reactive Ion Etching (RIE), using the photoresist pattern 210A as an etching mask. The photoresist pattern 210A is thereby transcribed into the insulating layer 200A, simultaneously forming the via hole H and the trench T. That is, the shape of the photoresist pattern 210A shown in example FIG. 5B is transcribed into the insulating layer 200, as it is. Here, the via hole H may be deeper than the trench T, while the trench T may be wider than the via hole H. The trench T may be effectively formed above the via hole H.

As described above, the method of manufacturing the semiconductor device in accordance with embodiments simultaneously forms the via hole H and the trench T using only one three-state mask 300 rather than two two-state masks 14 and 60. Therefore, there is no possibility that misalignment between the via hole H and the trench T occurs. Further, the number of masks used to form the via hole H and the trench T is reduced, and a manufacturing process of the semiconductor device is simplified.

A photoresist residue 210B may remain over the upper surface of the insulating layer 200A, after the via hole H and the trench T are simultaneously formed by etching, as shown in example FIG. 5C. Therefore, as shown in example FIG. 5D, the photoresist residue 210B may be removed by ashing.

Thereafter, a metal layer 400A to fill the via hole H and the trench T may be formed. For example, if the metal layer 400A is a copper layer, the metal layer 400A may be formed by Physical Vapor Deposition (PVD), Chemical Vapor Deposition (CVD), or electroplating. If the metal layer 400A is formed by electroplating, a seed copper film may be deposited over the entire surface of the insides of the via hole H and the trench T by PVD or DVD, as shown in example FIG. 5D. Then, a metal material 400 such as copper may be formed in a thick layer over the upper surface of the insulating layer 200A by soaking the deposition results in an electrolyte, as shown in example FIG. 5E. Thereafter, Chemical Mechanical Polishing (CMP) of the metal material 400 shown in example FIG. 5E may be carried out until the upper surface of the insulating layer 200A is exposed, thereby forming the metal layer 400A, as shown in example FIG. 5F. A diffusion barrier film may be further formed between the metal layer 400A and the insulating layer 200A shown in example FIG. 5F, but a detailed description thereof will be omitted herein.

As described above, in a three-state mask and a method of manufacturing a semiconductor device using the same in accordance with embodiments, one lithography process is performed using a single three-state mask rather than performing two lithography processes using two two-state masks. Thus two lithography processes may be shortened into one lithography process. If the semiconductor device is manufactured using a dual damascene process with the three-state mask, a hole and a trench may be simultaneously formed using the three-state mask. Misalignment between the hole and the trench is eliminated, and lowering of a sheet resistance (Rₛ) characteristic due to misalignment is prevented. Further, the hole and the trench may be simultaneously formed by carrying out just one lithography process. Thus the dual damascene process is simplified, and the number of masks used in the dual damascene process is reduced, to just one three-state mask. A manufacturing cost of the semiconductor device is therefore reduced.

It will be obvious and apparent to those skilled in the art that various modifications and variations can be made in the embodiments disclosed. Thus, it is intended that the disclosed embodiments cover the obvious and apparent modifications and variations, provided that they are within the scope of the appended claims and their equivalents.

What is claimed is:

1. A mask used during exposure of a lithography process and formed in a regular pattern, comprising:
a first transmission region to transmit substantially all incident light;
second transmission regions to transmit a portion of incident light; and
shield regions to block transmission of light.

2. The three-state mask according to claim 1, wherein the second transmission regions transmit 20% to 30% of light.

3. The three-state mask according to claim 1, wherein the second transmission regions are made of molybdenum silicide.

4. The three-state mask according to claim 1, wherein the shield regions are made of chrome.

5. The three-state mask according to claim 1, wherein the second transmission regions perform Phase Shift Masking on incident light.

6. The three-state mask according to claim 1, wherein the shield regions are formed in a region surrounding the first and second transmission regions.

7. The three-state mask according to claim 1, wherein the first transmission region is interposed between the second transmission parts.

8. The three-state mask according to claim 1, wherein the first transmission region has a ring shape.

9. A method comprising:
preparing a three-state mask including a first transmission region to transmit substantially all incident light, second transmission regions to transmit a portion of incident light, and shield regions to substantially block transmission of light;
forming an insulating layer over the upper surface of a semiconductor substrate;
coating a photoresist to the upper surface of the insulating layer;
patterning the photoresist by a lithography process using the three-state mask; and
simultaneously forming a via hole and a trench by transcribing the obtained photoresist pattern into the insulating layer.

10. The method according to claim 9, including removing, by ashing, a photoresist residue remaining after the simultaneous formation of the via hole and the trench.

11. The method according to claim 9, including forming a metal layer filling the via hole and the trench.

12. The method according to claim 9, wherein the patterning of the photoresist includes:
exposing the photoresist using the three-state mask; and
entirely dissolving the photoresist at a region exposed by light having passed through the first transmission region.

13. The method according to claim 12, wherein the patterning of the photoresist includes:
partially dissolving the photoresist at regions exposed by light having passed through the second transmission regions.

14. The method according to claim 13, wherein the patterning of the photoresist includes:
not dissolving the photoresist at regions shielded from light exposure by the shield regions.

15. The method according to claim 9, wherein the via hole is deeper than the trench.

16. The method according to claim 9, wherein the trench is wider than the via hole.

17. The method according to claim 9, wherein the trench is formed above the via hole.

18. The method according to claim 9, wherein transcribing the obtained photoresist pattern into the insulating layer includes etching the insulating layer using the photoresist pattern as a mask.

19. The method according to claim 11, including performing a chemical mechanical polishing process on the metal layer.

20. The method according to claim 11, including forming the metal layer using copper.
